(19) United States
(12) Patent Application Publication
(10) Pub. No.: US 2021/0368653 A1
(43) Pub. Date: Nov. 25, 2021

(54) HEAT TRANSFER MEDIUM AND HEAT TRANSFER SYSTEM

(71) Applicants: DENSO CORPORATION, Kariya-city (JP); TANIKAWAYUKA KOGYO CO., LTD., Yokohama-shi (JP)

(72) Inventors: Takuya FUSE, Kariya-city (JP); Kouji INAGAKI, Kariya-city (JP); Kenji NAKAMURA, Kariya-city (JP); Teru YAMADA, Yokohama-shi (JP); Kazumi SUZUKI, Yokohama-shi (JP)

(21) Appl. No.: 17/393,964

(22) Filed: Aug. 4, 2021

Related U.S. Application Data
(63) Continuation of application No. PCT/JP2020/004571, filed on Feb. 6, 2020.

(30) Foreign Application Priority Data
Feb. 8, 2019 (JP) 2019-021281

(51) Int. Cl. H05K 7/20; C09K 5/10

(52) U.S. Cl. CPC H05K 7/20363; C09K 5/10

(57) ABSTRACT

A heat transfer medium is used for a heat transfer system including a refrigerant cycle device through which a refrigerant circulates and a heat transfer medium circuit having an electric device. The medium includes an anhydrous liquid that does not contain water and is made of a substance having a polarity less than water. The anhydrous liquid is cooled by heat exchange with the refrigerant and absorbs heat from the electric device while circulating through the heat transfer medium circuit. Accordingly, the low viscosity of the heat transfer medium at a low temperature can be secured. Further, by using an anhydrous liquid without water as the heat transfer medium, it is possible to suppress an increase in an electrical conductivity of the heat transfer medium over time.

### CROSS REFERENCE TO RELATED APPLICATIONS

This application is a continuation application of International Patent Application No. PCT/JP2020/004571 filed on Feb. 6, 2020, which designated the U.S. and claims the benefit of priority from Japanese Patent Application No. 2019-021281 filed on Feb. 8, 2019. The entire disclosure of all of the above application is incorporated herein by reference.

### TECHNICAL FIELD

The present disclosure relates to a heat transfer medium and a heat transfer system.

### BACKGROUND ART

A device that cools a low-temperature cooling water by exchanging heat between a refrigerant of a refrigeration cycle system and the low-temperature cooling water in a low-temperature cooling water circuit at a chiller has been known. In this device, an ethylene glycol aqueous solution or the like is used as the low-temperature cooling water.

### SUMMARY

According to a first aspect of the present disclosure, a heat transfer medium is for a heat transfer system including a refrigerant cycle device through which a refrigerant circulates and a heat transfer medium circuit having an electric device. The heat transfer medium includes an anhydrous liquid that does not contain water and is made of a substance having a polarity less than water. The anhydrous liquid is cooled by heat exchange with the refrigerant and absorbs heat from the electric device while circulating through the heat transfer medium circuit.

According to a second aspect of the present disclosure, a heat transfer system includes the heat transfer medium circuit through which the heat transfer medium circulates, a refrigeration cycle device through which a refrigerant circulates, a heat exchanger that cools the heat transfer medium through heat exchange between the refrigerant and the heat transfer medium, and an electric device disposed in the heat transfer medium circuit. The heat transfer medium absorbs heat from the electric device.

### BRIEF DESCRIPTION OF DRAWINGS

FIG. 1 is a diagram showing an example of a heat transfer system according to the present disclosure.

FIG. 2 is a diagram showing a modification to the heat transfer system.

FIG. 3 is a diagram showing another modification to the heat transfer system.

FIG. 4 is a diagram showing yet another modification to the heat transfer system.

### DESCRIPTION OF EMBODIMENTS

To begin with, a relevant technology will be described first only for understanding the following embodiment. Since the above-described ethylene glycol aqueous solution has a high viscosity at a low temperature, the pressure loss in the low temperature cooling water circuit may increase. Therefore, the pumping power for circulating the low-temperature cooling water has to be increased. Further, since the ethylene glycol aqueous solution increases in an electrical conductivity in use, a large-scale insulation measure would be required to prevent electric leakage if it is used for carrying heat generated in an electric device such as a battery,.

In view of the above, it is an objective of the present disclosure to suppress an increase in viscosity of the heat transfer medium at a low temperature and to maintain a low electrical conductivity of the heat transfer medium.

As described above, according to the first aspect of the present disclosure, a heat transfer medium is for a heat transfer system including a refrigerant cycle device through which a refrigerant circulates and a heat transfer medium circuit having an electric device. The heat transfer medium includes an anhydrous liquid that does not contain water and is made of a substance having a polarity less than water. The anhydrous liquid is cooled by heat exchange with the refrigerant and absorbs heat from the electric device while circulating through the heat transfer medium circuit.

According to the second aspect of the present disclosure, a heat transfer system includes the heat transfer medium circuit through which the heat transfer medium circulates, a refrigeration cycle device through which a refrigerant circulates, a heat exchanger that cools the heat transfer medium through heat exchange between the refrigerant and the heat transfer medium, and an electric device disposed in the heat transfer medium circuit. The heat transfer medium absorbs heat from the electric device.

Accordingly, the low viscosity of the heat transfer medium at a low temperature can be ensured. Therefore, even under a low temperature environment, an increase in pressure loss in the heat transfer medium circuit can be suppressed, and an increase in pumping power can be suppressed.

Further, by using an anhydrous liquid without water as a heat transfer medium, it is possible to suppress an increase in an electrical conductivity of the heat transfer medium over time. As a result, it is not necessary to take a large-scale insulation measure for the heat transfer system.

Further, since the heat transfer medium has an insulation property, it is possible to have the heat transfer medium brought into direct contact with an electric device, and thus the electric device can be directly cooled by the heat transfer medium. As a result, the heat exchange efficiency between the electric device and the heat transfer medium at a low temperature can be improved, and the thermal resistance can be lowered.

Hereinafter, a most suitable embodiment to which the heat transfer system of the present disclosure is applied will be described with reference to the drawings.

The heat transfer system 1 of the present embodiment is mounted in an electric vehicle that obtains a driving force for traveling the vehicle from a traveling electric motor. Alternatively, the heat transfer system 1 of the present embodiment may be mounted in a hybrid car which obtains a driving force for traveling of the vehicle from both an engine (i.e., an internal combustion engine) and a traveling electric motor. The heat transfer system 1 of the present embodiment serves as an air-conditioner for adjusting the temperature in a vehicle interior, and also serves as a temperature control device for adjusting the temperature of the battery 33 or the like mounted in the vehicle.

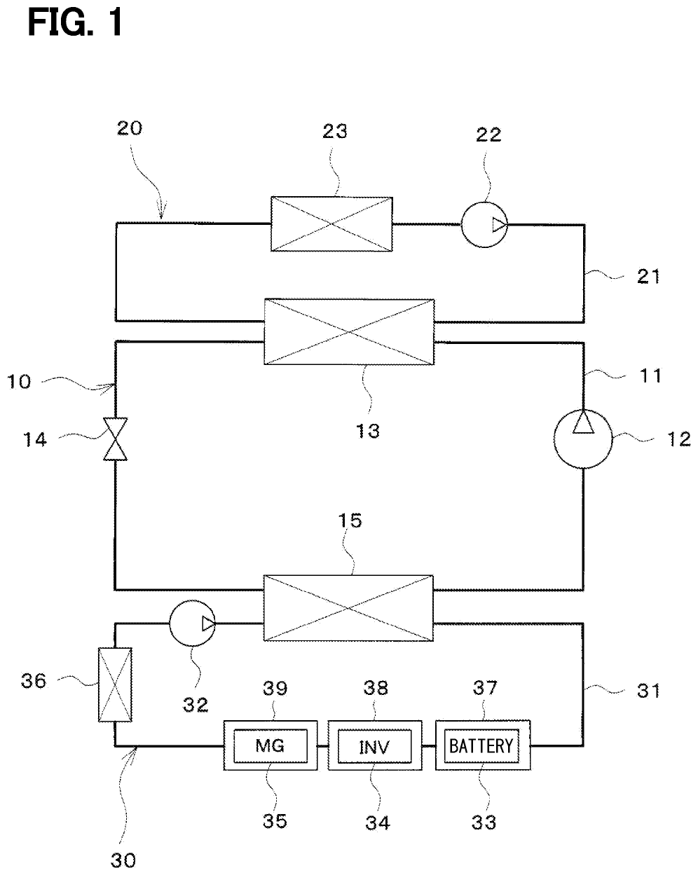

As shown in FIG. 1, the heat transfer system 1 includes a refrigeration cycle device 10, a high-temperature medium circuit 20, and a low-temperature medium circuit 30. In the high-temperature medium circuit 20 and the low-temperature medium circuit 30, heat is transferred through the heat transfer medium. The heat transfer medium in the low-temperature medium circuit 30 has a lower temperature than the heat transfer medium in the high-temperature medium circuit 20. Thereafter, the heat transfer medium in the high-temperature medium circuit 20 may be also referred to as a high-temperature heat transfer medium, and the heat transfer medium in the low-temperature medium circuit 30 is also referred to as a low-temperature heat transfer medium. The low-temperature medium circuit 30 corresponds to the heat transfer medium circuit.

The refrigeration cycle device 10 is a vapor compression refrigerator and has a refrigerant circulation passage 11 through which a refrigerant circulates. The refrigeration cycle device 10 serves as a heat pump that pumps heat from the low-temperature heat transfer medium in the low-temperature medium circuit 30 to the refrigerant.

According to the refrigeration cycle device 10 of the present embodiment, a Freon-based refrigerant is adopted as the refrigerant to constitute a subcritical refrigeration cycle in which a high-pressure refrigerant does not exceed a critical pressure of the refrigerant. A compressor 12, a condenser 13, an expansion valve 14, and an evaporator 15 for a heat transfer medium are arranged in the refrigerant circulation passage 11.

The compressor 12 may be an electric compressor that is driven by power supplied from the battery 33. The compressor 12 is configured to draw, compresses, and discharges the refrigerant. The condenser 13 is a high-pressure heat exchanger that condenses a high-pressure refrigerant by exchanging heat between the high-pressure refrigerant discharged from the compressor 12 and the heat transfer medium in a high-temperature medium circuit 20. In the condenser 13, the heat transfer medium in the high-temperature medium circuit 20 is heated by the high-pressure refrigerant in the refrigeration cycle device 10.

The expansion valve 14 serves as a decompressor that is configured to decompress and expand a liquid-phase refrigerant flowing out of the condenser 13. The expansion valve 14 is a temperature-type expansion valve having a temperature sensor and configured to move a valve element using a mechanical mechanism such as a diaphragm.

The heat transfer medium evaporator 15 is a low-pressure heat exchanger that evaporates the low-pressure refrigerant by exchanging heat between the low-pressure refrigerant flowing out of the expansion valve 14 and the heat transfer medium in the low-temperature medium circuit 30. The vapor-phase refrigerant evaporated in the heat transfer medium evaporator 15 is sucked into the compressor 12 and then is compressed.

The heat transfer medium evaporator 15 is a chiller that cools the heat transfer medium in the low-temperature medium circuit 30 with the low-pressure refrigerant in the refrigeration cycle device 10. In the heat transfer medium evaporator 15, the heat of the heat transfer medium in the low temperature medium circuit 30 is absorbed by the refrigerant of the refrigeration cycle device 10. The heat transfer medium evaporator 15 corresponds to a heat exchanger.

The high-temperature medium circuit 20 has a high-temperature circulation passage 21 in which the high-temperature heat transfer medium circulates. Ethylene glycol-based antifreeze (LLC) or the like can be used as the high-temperature heat transfer medium. The high-temperature heat transfer medium is enclosed in pipes constituting the high-temperature circulation passage 21. The high-temperature medium circuit 20 of the present embodiment is a closed-type circuit without a pressure adjusting valve that opens when the pressure of the high-temperature heat transfer medium exceeds a predetermined value.

A high-temperature pump 22, a heater core 23, and a condenser 13 are arranged in the high-temperature circulation passage 21.

The high-temperature pump 22 draws and discharges the heat transfer medium circulating through the high-temperature circulation passage 21. The high-temperature pump 22 is an electric pump. The high-temperature pump 22 adjusts the flow rate of the heat transfer medium circulating in the high-temperature medium circuit 20.

The heater core 23 is a heat exchanger for heating air. The heater core 23 is configured to perform heat exchange between the heat transfer medium in the high-temperature medium circuit 20 and air supplied into the vehicle cabin to heat the air. In the heater core 23, the air blown into the vehicle cabin is heated by the heat transfer medium.

The air heated at the heater core 23 is supplied into the vehicle cabin to heat the vehicle cabin. Heating by the heater core 23 is mainly performed in winter. In the heat transfer system of the present embodiment, heat of an outside air absorbed by the low-temperature heat transfer medium in the low-temperature medium circuit 30 is pumped up by the refrigeration cycle device 10 to the high-temperature heat transfer medium in the high-temperature medium circuit 20 and used for heating the vehicle cabin.

The low-temperature medium circuit 30 has a low-temperature circulation passage 31 in which the low-temperature heat transfer medium circulates. The low-temperature heat transfer medium is enclosed in pipes constituting the low-temperature circulation passage 31. The low-temperature medium circuit 30 of the present embodiment is a closed-type circuit without a pressure adjusting valve that opens when the pressure of the low-temperature heat transfer medium exceeds a predetermined value. Details of the low-temperature heat transfer medium will be described later.

A low-temperature pump 32, a heat transfer medium evaporator 15, a battery 33, an inverter 34, a motor generator 35, and an external heat exchanger 36 are arranged in the low-temperature circulation passage 31. In the example shown in FIG. 1, the battery 33, the inverter 34, the motor generator 35, the external heat exchanger 36, and the low-temperature pump 32 are connected to each other in this order in the flow direction of the low-temperature heat transfer medium, but the connecting order is not necessarily limited to this order. Further, in the example shown in FIG. 1, the battery 33, the inverter 34, the motor generator 35, the external heat exchanger 36, and the low-temperature pump 32 are connected to each other in series, but one or more of these devices may be connected to other devices in parallel.

The low-temperature pump 32 draws and discharges the heat transfer medium circulating in the low-temperature circulation passage 31. The low-temperature pump 32 is an electric pump. The low-temperature pump 32 adjusts the flow rate of the heat transfer medium circulating in the low-temperature medium circuit 30.

The battery 33 is a rechargeable/dischargeable secondary battery, and for example, a lithium ion battery can be used. As the battery 33, an assembled battery formed of a plurality of battery cells can be used.

The battery 33 can be charged with power supplied from an external power source (in other words, a commercial power source) when the vehicle is stopped. The power stored in the battery 33 may be supplied to the electric motor for driving the vehicle, and also be supplied to various devices, which are mounted in the vehicle, such as various electric components in the vehicle thermal management device 10.

The inverter 34 converts DC power supplied from the battery 33 into AC power and outputs it to the motor generator 35. The motor generator 35 is configured to generate a running force using the electric power output from the inverter 34 and generate regenerative electric power during deceleration or traveling downhill.

The external heat exchanger 36 exchanges heat between the heat transfer medium in the low-temperature medium circuit 30 and the outside air. The external heat exchanger 36 receives an outside air supplied from an outdoor blower (not shown).

The battery 33, the inverter 34, and the motor generator 35 are electric devices that operate using electricity and generate heat during operation. The battery 33, the inverter 34, and the motor generator 35 are cooling target devices that are cooled by the low-temperature heat transfer medium.

In the present embodiment, the battery 33 is housed in a first cooling container 37, the inverter 34 is housed in a second cooling container 38, and the motor generator 35 is housed in a third cooling container 39. In the cooling containers 37 to 39, a low-temperature heat transfer medium that circulates in the low-temperature circulation passage 31 circulates. Therefore, the battery 33, the inverter 34, and the motor generator 35 are immersed in the low-temperature heat transport medium inside the cooling containers 37 to 39, respectively. That is, the cooling containers 37 to 39 are direct cooling type coolers, and the low temperature side heat transport medium comes into direct contact with the battery 33, the inverter 34, and the motor generator 35 to exchange heat.

In the cooling containers 37 to 39, heat is transferred from the battery 33, the inverter 34, and the motor generator 35, which are the devices to be cooled, to the low-temperature heat transfer medium. In the external heat exchanger 36, heat is transferred from the outside air to the low-temperature heat transfer medium. That is, the battery 33, the inverter 34, the motor generator 35, and the external heat exchanger 36 are heat absorbing devices that cause the low-temperature heat transfer medium to receive heat.

Next, the low-temperature heat medium will be described. It is desirable that the low-temperature heat transfer medium has low viscosity at a low temperature and high insulation property. Further, it is desirable that the low-temperature heat transfer medium has a large heat capacity, a boiling point higher than the maximum temperature under the use environment, a freezing point lower than the minimum temperature under the use environment, and high chemical stability.

In the present embodiment, as the low-temperature heat transfer medium, a substance that is an anhydrous liquid not containing water and has a lower polarity than water is used. As the anhydrous liquid, any one of an anhydrous alcohol-based liquid, an anhydrous amide-based liquid, an anhydrous ester-based liquid, an anhydrous silicone-based liquid, and an anhydrous fluorine-based liquid can be used. These anhydrous liquids have a property of low viscosity at a low temperature and a high insulation property.

The anhydrous alcohol-based liquid, the anhydrous amide-based liquid, and the anhydrous ester-based liquid are more preferable in terms of viscosity, heat capacity, boiling point, and freezing point when used as the low-temperature heat transport medium. The anhydrous silicone-based liquid and the anhydrous fluorine-based liquid are more preferable in terms of chemical stability and insulation properties when used as the low-temperature heat transport medium. Further, the anhydrous silicone-based liquid and the anhydrous fluorine-based liquid have lubricity.

As the anhydrous alcohol-based liquid, any one of methanol, ethanol, and propanol, which are alcohols having 1 to 3 carbon atoms, can be used. The propanols include normal propanol (NPA) and isopropanol (IPA).

Methanol has a melting point of −97° C. and a boiling point of 64.5° C. Ethanol has a melting point of −114° C. and a boiling point of 78.3° C. Normal propanol has a melting point of −126° C. and a boiling point of 97.2° C. Isopropanol has a melting point of −89.5° C. and a boiling point of 82.4° C.

Alcohol having appropriate properties may be appropriately selected among alcohols having 1 to 3 carbon atoms according to the use environment. Normal propanol or isopropanol can be preferably used as the low-temperature heat transfer medium in the present embodiment.

The anhydrous alcohol-based liquid can ensure low viscosity at a low temperature by having the alcohol with the carbon number of 3 at most. Methanol has a kinematic viscosity of 1.35 mm²/s at −20° C. and a kinematic viscosity of 1.80 mm²/s at −35° C. The kinematic viscosity of normal propanol is 8.05 mm²/s at −20° C. and 13.1 mm²/s at −35° C. The ethylene glycol antifreeze (LLC) as a comparative example has a kinematic viscosity of 29.6 mm²/s at −20° C. and a kinematic viscosity of 89.5 mm²/s at −35° C. Accordingly, the anhydrous alcohol-based liquid of the present embodiment can secure a low viscosity at a low temperature.

As the anhydrous amide liquid, dimethylformamide (DMF), for example, can be used. Dimethylformamide has a melting point of −61° C. and a boiling point of 153° C. Dimethylformamide has a kinematic viscosity of 1.63 mm²/s at −20° C. and a kinematic viscosity of 2.25 mm²/s at −35° C. Accordingly, the anhydrous amide liquid of the present embodiment can secure a low viscosity at a low temperature.

As the anhydrous ester-based liquid, a carbonic acid ester or a carboxylic acid ester can be used, for example. As the carboxylic acid, formic acid or acetic acid can be used, for example. As the alcohol that binds to carbonic acid or carboxylic acid, for example, an alcohol having 1 to 3 carbon atoms (i.e., methanol, ethanol, propanol) can be used.

As the anhydrous silicone-based liquid, for example, silicone oil, which is a linear polymer having a siloxane bond, can be used. Among the silicone oils, dimethyl silicone oil can be preferably used as the low-temperature heat transfer medium. Silicone oil has high chemical stability and insulation property. In addition, silicone oil has lubricity.

As the anhydrous fluorine-based liquid, fluorocarbon can be used, for example. Fluorocarbon is a substance in which a part of hydrogen contained in a hydrocarbon is replaced with fluorine, and known as Fluorinert (a registered trademark of 3M Company). Fluorocarbons have high chemical stability and insulation property. In addition, fluorocarbon has lubricity.

According to the present embodiment described above, by using an anhydrous liquid as the low-temperature heat transfer medium, it is possible to suppress an increase in viscosity under a low-temperature environment as compared to an ethylene glycol antifreeze liquid. Therefore, even under a low-temperature environment, an increase in pressure loss generated when the low-temperature heat transfer medium flows through the low-temperature medium circuit 30 can be suppressed, and an increase in power of the low-temperature pump 32 can be avoided.

Further, since the low-temperature medium circuit 30 can suppress an increase in pressure loss generated when the low-temperature heat transfer medium flows, the external heat exchanger 36 can be easily miniaturized by narrowing the passage for the low-temperature heat transfer medium. As a result, the degree of design freedom can be improved. Further, since the flow rate of the low-temperature heat transfer medium passing through the external heat exchanger 36 is increased, frost formation on the external heat exchanger 36 can be suppressed.

Further, since the increase in viscosity of the low-temperature heat transfer medium under a low-temperature environment can be suppressed, the flow rate of the low-temperature heat transfer medium can be increased as compared to the ethylene glycol antifreeze solution. As a result, the flow rate of the low-temperature heat transfer medium can be increased, and the heat transfer efficiency of the low-temperature heat transfer medium can be further improved. Further, by improving the heat transfer efficiency of the low-temperature heat transfer medium, it is possible to improve the heat transfer efficiency of the entire system including the external heat exchanger 36.

Further, by using an anhydrous liquid not containing water as the low-temperature heat transfer medium, it is possible to suppress an increase in an electrical conductivity of the low-temperature heat transfer medium over time. As a result, it is not necessary to take a large-scale insulation measure for the heat transfer system 1.

Further, since the low-temperature heat transfer medium has an insulation property, the low-temperature heat transfer medium and the electric devices 33 to 35 can be brought into direct contact with each other, and thus the electric devices 33 to 35 can be directly cooled by the low-temperature heat transfer medium. As a result, the heat exchange efficiency between the electric devices 33 to 35 and the low-temperature heat transfer medium can be improved, and the thermal resistance can be lowered.

When an anhydrous alcohol-based liquid, an anhydrous amide-based liquid, or an anhydrous ester-based liquid is used as the low-temperature heat transfer medium, the heat transfer medium with high viscosity, heat capacity, boiling point, and freezing point can be obtained.

Further, when an anhydrous silicone-based liquid or an anhydrous fluorine-based liquid is used as the low-temperature heat transfer medium, the heat transfer medium having high chemical stability and insulating properties can be obtained.

Further, when an anhydrous silicone-based liquid or an anhydrous fluorine-based liquid having lubricity is used as the low-temperature heat transfer medium, the low-temperature heat transfer medium can also serve as a lubricating oil for, e.g., the motor generator 35.

The present disclosure is not limited to the embodiments described above, and various modifications can be made as follows within a range not departing from the spirit of the present disclosure. Further, means disclosed in the above embodiments may be appropriately combined within an enabling range.

For example, in the above embodiment, the battery 33, the inverter 34, and the motor generator 35 are individually housed in the cooling container, but two or more of the electric devices may be housed in the single cooling container.

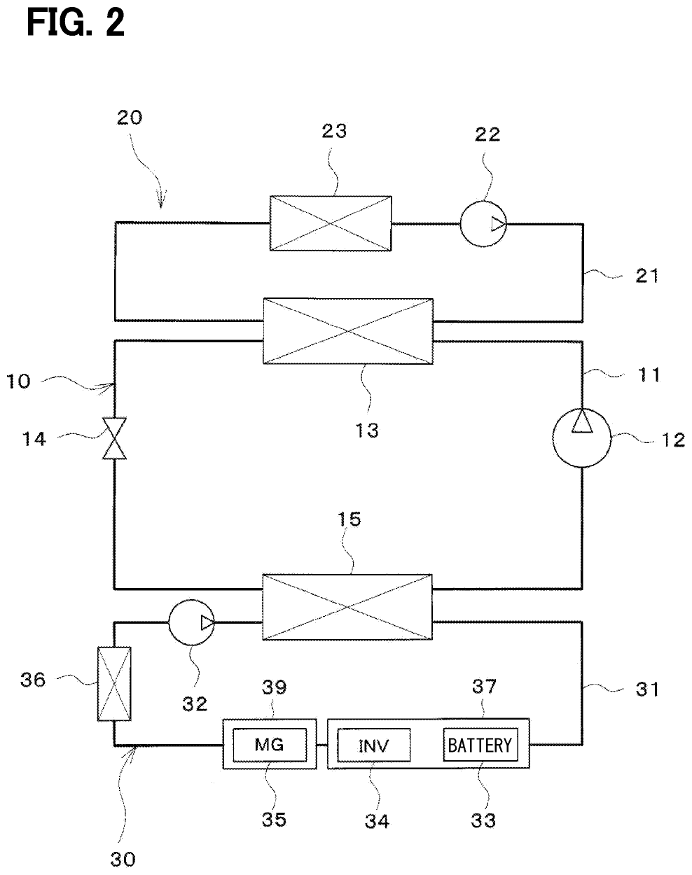

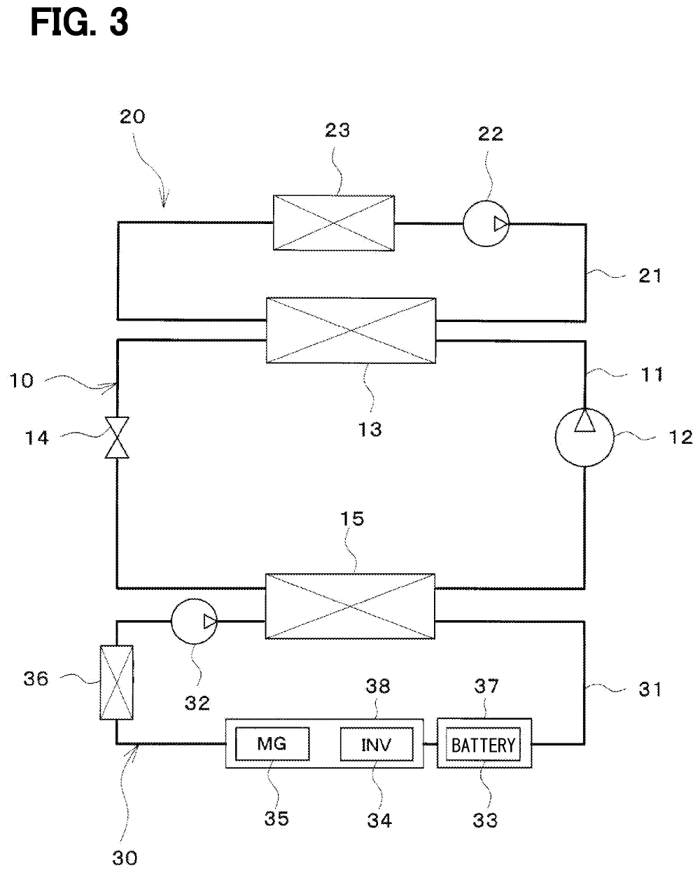

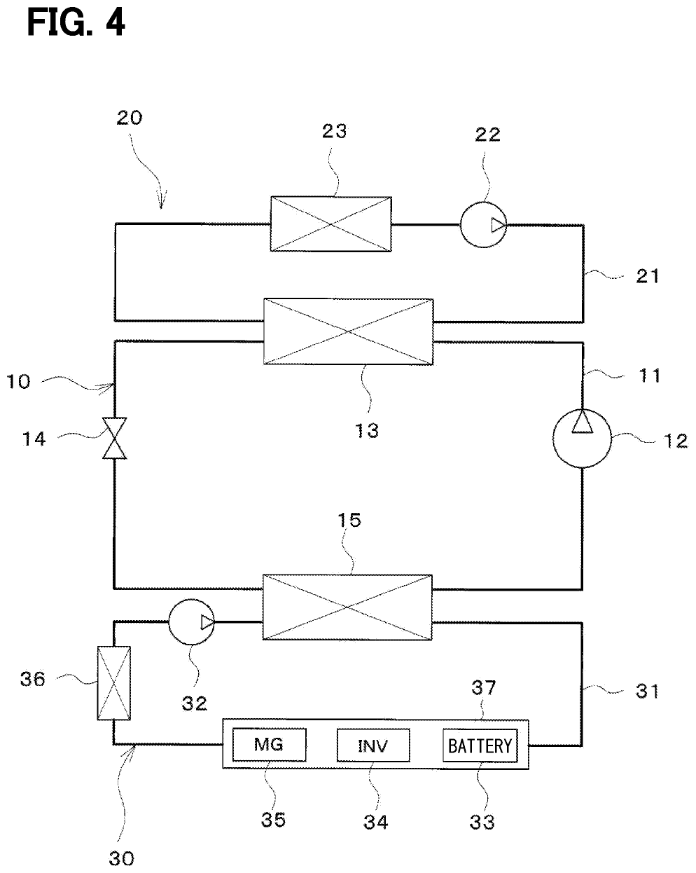

For example, as shown in FIG. 2, the battery 33 and the inverter 34 may be housed in the single cooling container 37, and as shown in FIG. 3, the inverter 34 and the motor generator 35 may be housed in the single cooling container 38. Further, as shown in FIG. 4, the battery 33, the inverter 34, and the motor generator 35 may be housed in the single cooling container 37.

Although the present disclosure has been described in accordance with embodiments, it is understood that the present disclosure is not limited to such embodiments or structures. The present disclosure encompasses various modifications and variations within the scope of equivalents. In addition, while the various combinations and configurations, which are preferred, other combinations and configurations, including more, less or only a single element, are also within the spirit and scope of the present disclosure.

1. A heat transfer medium for a heat transfer system including a refrigerant cycle device through which a refrigerant circulates and a heat transfer medium circuit having an electric device , the medium comprising:
an anhydrous liquid that does not contain water and is made of a substance having a polarity less than water, wherein
the anhydrous liquid is cooled by heat exchange with the refrigerant and absorbs heat from the electric device while circulating through the heat transfer medium circuit.

2. The heat transfer medium according to claim 1, wherein
the anhydrous liquid is an anhydrous alcohol-based liquid.

3. The heat transfer medium according to claim 2, wherein
the anhydrous alcohol-based liquid is an alcohol having 1 to 3 carbon atoms.

4. The heat transfer medium according to claim 1, wherein
the anhydrous liquid is an anhydrous amide liquid.

5. The heat transfer medium according to claim 4, wherein
the anhydrous amide liquid is a dimethylformamide.

6. The heat transfer medium according to claim 1, wherein
the anhydrous liquid is an anhydrous ester liquid.

7. The heat transfer medium according to claim 6, wherein.
the anhydrous ester-based liquid is:
a carbonic acid ester where a carbonic acid and an alcohol having 1 to 3 carbon atoms are bound to each other; or
a carboxylic acid ester where a carboxylic acid and an alcohol having 1 to 3 carbon atoms are bound to each other.

8. The heat transfer medium according to claim 1, wherein
the anhydrous liquid is an anhydrous silicone liquid.

9. The heat transfer medium according to claim 8, wherein
the anhydrous silicone-based liquid is a dimethyl silicone oil.

10. The heat transfer medium according to claim 1, wherein
the anhydrous liquid is an anhydrous fluorine-based liquid.

11. The heat transfer medium according to claim 10, wherein
the anhydrous fluorine-based liquid is a fluorocarbon.

12. The heat transfer medium according to claim 1, wherein
the anhydrous liquid exchanges the heat with the electric device by directly coming into contact with the electric device.

13. A heat transfer system, comprising:
the heat transfer medium circuit through which the heat transfer medium according to claim 1 circulates;
a refrigeration cycle device through which a refrigerant circulates;
a heat exchanger that cools the heat transfer medium through heat exchange between the refrigerant and the heat transfer medium; and
an electric device disposed in the heat transfer medium circuit, wherein
the heat transfer medium absorbs heat from the electric device.
